(19) United States
(12) Patent Application Publication
(10) Pub. No.: US 2026/0239950 A1
(43) Pub. Date: Aug. 13, 2026

(54) SEMICONDUCTOR PACKAGE AND METHOD FOR FABRICATING THE SAME

(71) Applicant: Samsung Electronics Co., Ltd., Suwon-si (KR)

(72) Inventor: Hyun-Mook Choi, Suwon-si (KR)

(73) Assignee: Samsung Electronics Co., Ltd., Suwon-si (KR)

(21) Appl. No.: 19/328,008

(22) Filed: Sep. 12, 2025

(30) Foreign Application Priority Data
Feb. 7, 2025 (KR) 10-2025-0015601

(51) Int. Cl. H01L 23/48; H01L 23/00; H01L 23/538; H01L 25/04; H01L 25/16

(52) U.S. Cl. CPC H10W 20/20; H10W 70/611; H10W 70/65; H10W 90/00; H10W 90/724

(57) ABSTRACT

A semiconductor package that prevents a decrease in a cell area in a memory die is provided to which PIM technology is applied. The semiconductor package comprises a package substrate, a logic die arranged on the package substrate, and a plurality of memory dies sequentially stacked on the logic die, wherein at least one of the plurality of memory dies includes a first chip and a second chip, which are stacked, the first chip includes a memory cell region, and the second chip includes a processing in memory (PIM) region.

### CROSS-REFERENCE TO RELATED APPLICATIONS

This application claims priority to and the benefit under 35 U.S.C. § 119(a)-(d) of Korean Patent Application No. 10-2025-0015601 filed on Feb. 7, 2025, in the Korean Intellectual Property Office, the entire disclosure of which is incorporated herein by reference.

### FIELD

The present disclosure relates to a semiconductor package and a method for fabricating the same.

### BACKGROUND

Recent applications, such as learning systems such as deep neural networks, require a lot of computational and memory capabilities to train different data sets and learn with high accuracy. Moreover, as applications, such as high-performance computing and graphic operations, become data-intensive and computationally intensive, energy efficiency and low latency become important. A technology known as Processing In Memory (PIM) provides additional computational capability by scheduling complex operations in logic dies of a memory (e.g., a dynamic random access memory (DRAM), etc.) closer to a place where data is located, as well as low-power technology processes, thereby solving such problems.

A high bandwidth memory (HBM) is a high-performance RAM interface for three-dimensional stacked memories (e.g., DRAM). It is used with high-performance graphics accelerators and network devices to access a lot of data. The HBM generally achieves a wider bandwidth while consuming less power, in a form factor substantially smaller than other DRAM technologies (e.g., DDR4, GDDR5, etc.). This may be achieved by stacking a plurality of memory dies (e.g., eight) together. This stacking may include an optional base die that includes a memory controller. The dies may be connected by through-silicon vias (TSV) and micro-bumps.

When the PIM technology is applied to the memory die, the memory die includes a memory cell region and a PIM region. Accordingly, the memory cell region may be reduced within the limited memory die.

### SUMMARY

An object of the present disclosure is to provide a semiconductor package that prevents a decrease in a cell area in a memory die to which PIM technology is applied.

Another object of the present disclosure is to provide a method for fabricating a semiconductor package that prevents a decrease in a cell area in a memory die to which PIM technology is applied.

The objects of the present disclosure are not limited to those mentioned above and additional objects of the present disclosure, which are not mentioned herein, will be clearly understood by those skilled in the art from the following description of the present disclosure.

According to some example embodiments of the present disclosure, a semiconductor package comprises a package substrate, a logic die arranged on the package substrate, and a plurality of memory dies sequentially stacked on the logic die, wherein at least one of the plurality of memory dies includes a first chip and a second chip, which are stacked, the first chip includes a memory cell region, and the second chip includes a processing in memory (PIM) region.

According to some example embodiments of the present disclosure, a semiconductor package comprises a package substrate; an interposer arranged on the package substrate, including a first region and a second region, which are adjacent to one another; a processor arranged on the first region; a logic die arranged on the second region; and a plurality of memory dies sequentially stacked on the logic die, wherein at least one of the plurality of memory dies includes a first chip and a second chip, which are stacked, the first chip includes a memory cell region, and the second chip includes a processing in memory (PIM) region.

According to some example embodiments of the present disclosure, a semiconductor package comprises a package substrate; an interposer arranged on the package substrate, including a first region and a second region, which are adjacent to one another; a processor arranged on the first region; a logic die arranged on the second region; and a plurality of memory dies sequentially stacked on the logic die, wherein each of the plurality of memory dies includes a first chip and a second chip, which are sequentially stacked, the first chip includes a memory cell region, and the second chip includes a processing in memory (PIM) region, the logic die includes a first edge region facing the processor, each of the plurality of memory dies includes a second edge region that overlaps the first edge region, a first through electrode is formed in the first edge region, a second through electrode is formed in the second edge region, the second through electrode includes a first sub-through electrode formed in the first chip and a second sub-through electrode formed in the second chip, and the first through electrode, the first sub-through electrode, and the second sub-through electrode are electrically connected to one another.

A method for fabricating a semiconductor package according to some embodiments of the present disclosure to achieve the above objects comprises arranging an interposer on a package substrate, the interposer including a first region and a second region, which are adjacent to one another, arranging a processor on the first region, arranging a logic die on the second region, and sequentially stacking a plurality of memory dies on the logic die, wherein one of the plurality of memory dies includes a first chip and a second chip, which are stacked, the first chip includes a memory cell region, and the second chip includes a processing in memory (PIM) region and a peri region.

Details of the other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a conceptual view illustrating a semiconductor package according to some embodiments of the present disclosure;

FIG. 2 is a view illustrating a relation among a processor, a logic die, and a memory die, which are shown in FIG. 1;

FIG. 3 is a view illustrating a memory die shown in FIG. 1;

FIG. 4 is a conceptual view illustrating a first chip shown in FIG. 3;

FIG. 5 is a conceptual view illustrating a second chip shown in FIG. 3;

FIG. 6 is a view illustrating a structure of a memory die shown in FIG. 1;

FIG. 7 is a conceptual view illustrating effects of a semiconductor package according to some embodiments of the present disclosure;

FIGS. 8 to 11 are views illustrating an arrangement of a PIM region and a peri region in a semiconductor package according to some embodiments of the present disclosure;

FIG. 12 is a flow chart illustrating a method for fabricating a semiconductor package according to some embodiments of the present disclosure;

FIGS. 13 to 18 are views illustrating intermediate steps to describe a method for fabricating a memory die used in a semiconductor package according to some embodiments of the present disclosure;

FIG. 19 is a conceptual view illustrating a semiconductor package according to some embodiments of the present disclosure; and

FIG. 20 is a conceptual view illustrating a semiconductor package according to some embodiments of the present disclosure.

### DETAILED DESCRIPTION

Hereinafter, the embodiments according to the present disclosure will be described in detail with reference to the accompanying drawings. The same reference numerals will be used for the same elements on the drawings and a repeated description of the corresponding elements will be omitted.

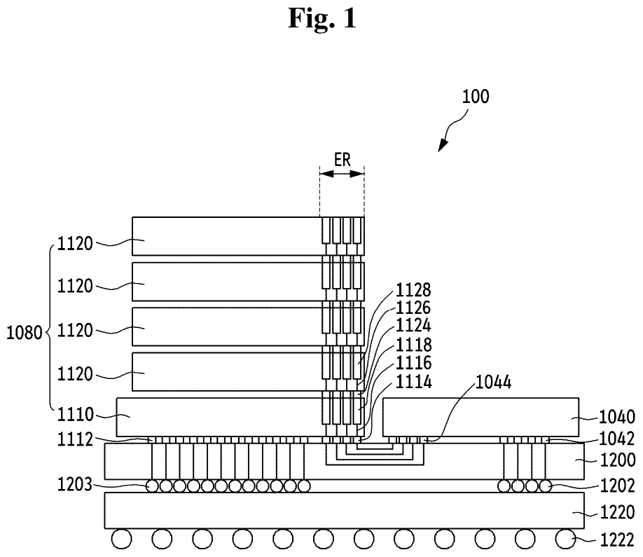

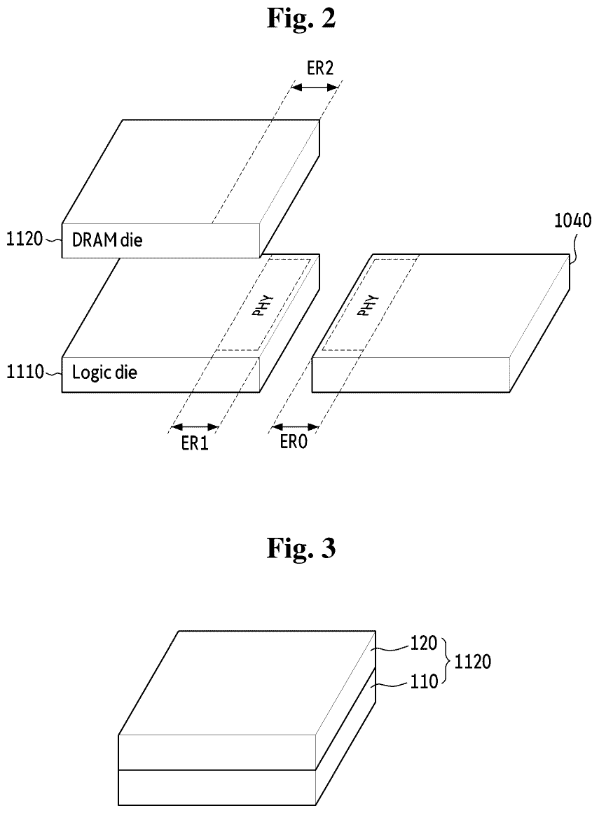

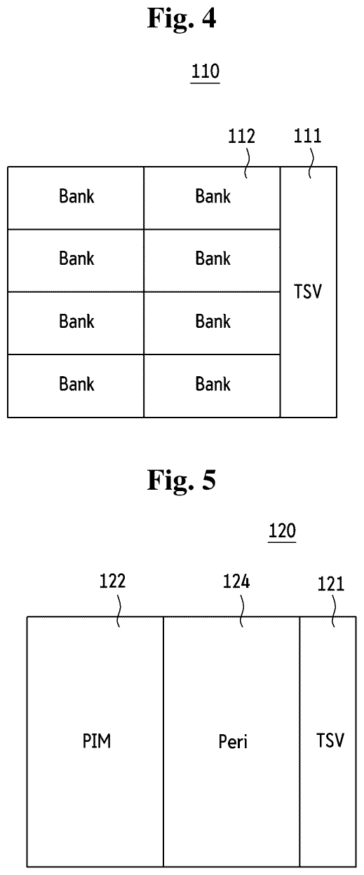

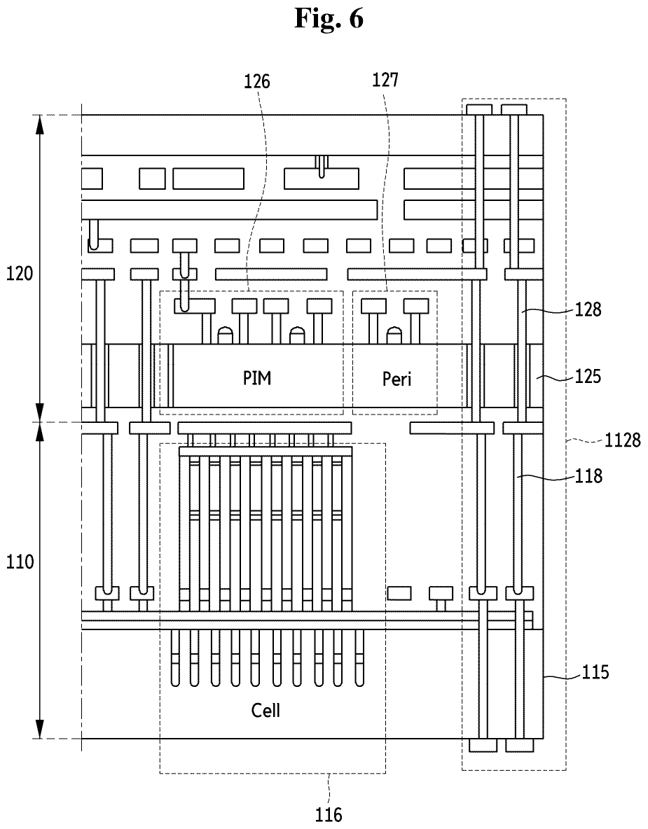

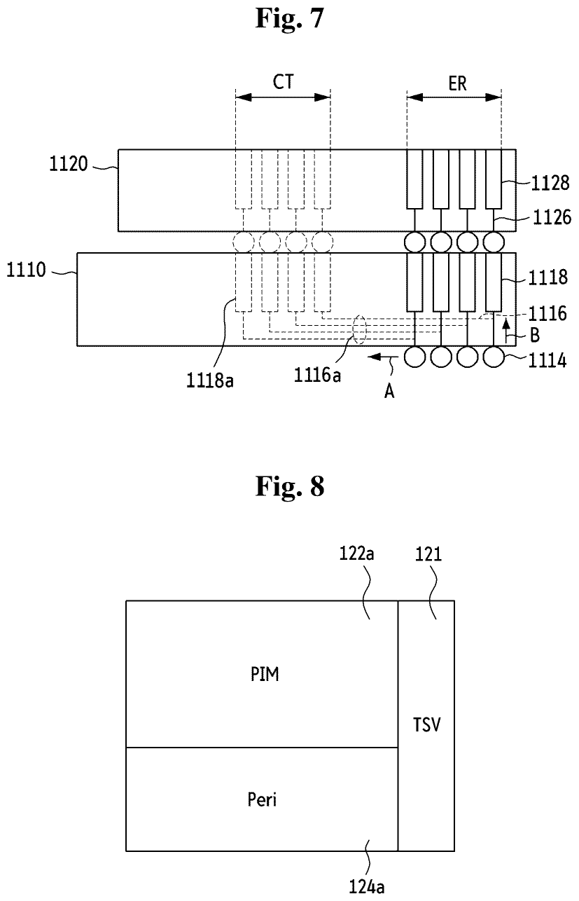

FIG. 1 is a conceptual view illustrating a semiconductor package according to some embodiments of the present disclosure. FIG. 2 is a view illustrating a relation among a processor, a logic die, and a memory die, which are shown in FIG. 1. FIG. 3 is a view illustrating a memory die shown in FIG. 1. FIG. 4 is a conceptual view illustrating a first chip shown in FIG. 3. FIG. 5 is a conceptual view illustrating a second chip shown in FIG. 3. FIG. 6 is a view illustrating a structure of a memory die shown in FIG. 1. FIG. 7 is a conceptual view illustrating effects of a semiconductor package according to some embodiments of the present disclosure.

First, referring to FIG. 1, a semiconductor package according to some embodiments of the present disclosure may include a plurality of integrated circuit dies. The plurality of integrated circuit dies may be aligned into, for example, a multichip module (MCM). The multichip module may be an electronic assembly, such as a package including a plurality of conductive terminals or pins, in which a plurality of integrated circuits, semiconductor dies, and/or other distinguished components are integrated on a unifying substrate and regarded as a single component (e.g., a larger IC) in use. Although FIG. 1 illustrates a high bandwidth memory (HBM) device as an example, it is only exemplary.

A semiconductor package 100 according to some embodiments of the present disclosure includes a package substrate 1220, an interposer 1200, a processor 1040, a logic die 1110, a plurality of memory dies 1120, and the like.

The package substrate 1220 may be configured to perform communication with other components or dies and the outside of the semiconductor package. A plurality of balls 1222 may be installed on a lower surface of the package substrate 1220, but the present disclosure is not limited thereto.

The interposer 1200 may include silicon or other substrates. A plurality of bumps 1202 and 1203 may be installed on a lower surface of the interposer 1200, but the present disclosure is not limited thereto. The interposer 1200 may be configured to perform communication between the processor 1040 and the logic die 1110. Also, the interposer 1200 may be configured to perform communication between the logic die 1110 and the package substrate 1220 and communication between the processor 1040 and the package substrate 1220.

The interposer 1200 may include a first region and a second region, which are adjacent to one another.

The processor 1040 is arranged on the first region of the interposer 1200. The processor 1040 may be configured to execute various instructions or perform logic operations.

A micro-bump 1042 is installed on a lower surface of the processor 1040 to electrically connect the processor 1040 to the interposer 1200.

The processor 1040 may be a central processing unit (CPU), and may include a specialized processing unit such as a graphic processing unit (GPU), an encryption processing unit, a physics processing unit, and a machine learning processing unit. The above-described examples are simply and partially shown embodiments, and the present disclosure is not limited thereto.

The stack 1080 is arranged on the second region of the interposer 1200. The stack 1080 includes a logic die 1110 and a plurality of stacked memory dies 1120.

The logic die 1110 may be configured to perform standard memory access coordination functions (e.g., page table translations, address mapping, write combination, etc.). In various embodiments, the logic die 1110 may include a memory management unit (MMU) centralized on the plurality of memory dies 1120, but is not limited thereto. Micro-bumps 1112 and 1114 are installed on a lower surface of the logic die 1110 to electrically connect the logic die 1110 to the interposer 1200.

The plurality of memory dies 1120 may be arranged to be perpendicular to one another. That is, the memory dies 1120 may have a structure in which one memory die 1120 is stacked on another memory die 1120. The memory die 1120 may be, for example, a DRAM memory die, but is not limited thereto. A micro-bump 1124 is installed on a lower surface of each of the plurality of memory dies 1120 to electrically connect the logic die 1110 to the memory die 1120. Also, the memory dies 1120 stacked up and down may be electrically connected to one another through the micro-bump 1124.

A device formed in the memory die 1120 may be implemented in various forms. For example, the device may be implemented as a Buried Channel Array Transistor Cell (BCAT), a Vertical Channel Transistor (VCT), a Vertical Stack DRAM (VS-DRAM), etc. In addition, SiGe or amorphous oxide (e.g., IGZO(InGaZnO)) as well as silicon may be used as a channel material.

The memory die 1120 may be configured to implement a processing in memory (PIM) function.

Furthermore, communication between the plurality of memory dies 1120 and the logic die 1110 may be performed through a through electrode (e.g., a through-silicon via (TSV)) and a vertical wiring. As shown in FIG. 1, a through electrode 1118 and/or a vertical wiring 1116 are formed in the logic die 1110. A through electrode 1128 and/or a vertical wiring 1126 are formed in the memory die 1120.

In particular, the through electrode 1118 in the logic die 1110 and the through electrode 1128 in the memory die 1120 are arranged in an edge region ER.

Referring to FIG. 2, the logic die 1110 includes an edge region ER1 located on the side facing the processor 1040. Also, the processor 1040 includes an edge region ERO located on the side facing the logic die 1110.

A physical layer interface is located in the edge region ERO of the processor 1040. In addition, a physical layer interface is located in the edge region ER1 of the logic die 1110.

In addition, an edge region ER2 of the memory die 1120 is located to overlap the edge region ER1 of the logic die 1110.

According to some embodiments of the present disclosure, the through electrode (see 1128 of FIG. 1) is installed in the edge region ER2 of the memory die 1120, and the through electrode (see 1118 of FIG. 1) is installed in the edge region ER1 of the logic die 1110. The through electrode 1128 and the through electrode 1118 are electrically connected to one another.

Referring to FIG. 3, at least one of the plurality of memory dies 1120 includes a first chip 110 and a second chip 120, which are stacked. Although the first chip 110 is shown as being arranged below the second chip 120, the present disclosure is not limited thereto. In contrast, the second chip 120 may be arranged below the first chip 110. Each of the plurality of memory dies 1120 may include the first chip 110 and the second chip 120, which are stacked.

Referring to FIGS. 4 and 5, the first chip 110 includes a memory cell region 112. Although the memory cell region 112 is shown as including eight memory banks, the present disclosure is not limited thereto. A sub-through electrode region 111 is arranged in the edge region (see ER2 of FIG. 2).

The second chip 120 includes a processing in memory (PIM) region 122. The second chip 120 may further include a peri region 124. A sub-through electrode region 121 is arranged in the edge region (see ER2 of FIG. 2).

The through electrode 1128 in the memory die 1120 described above includes a sub-through electrode region 111 formed in the first chip 110 and a sub-through electrode region 121 formed in the second chip 120. The sub-through electrode region 111 formed in the first chip 110 and the sub-through electrode region 121 formed in the second chip 120 are electrically connected to one another.

The peri region 124 may be arranged in the first chip 110 depending on design.

Also, the peri region 124 may be arranged between the PIM region 122 and the sub-through electrode region 121 (or the edge region ER2). This is because the peri region 124 is arranged more adjacent to the sub-through electrode region 121, so that a signal provided through the sub-through electrode region 121 may be processed more quickly.

As described above, the memory die 1120 is configured to include the two chips 110 and 120 that are stacked, thereby making sure of a sufficient size of the memory cell region 112 even though the PIM region 122 is added.

When the memory die is configured to include one chip, a memory cell region, a PIM region, and a peri region should be implemented in one chip. Therefore, the size of the memory cell region is inevitably reduced. On the other hand, as in some embodiments of the present disclosure, when the memory die 1120 is configured to include two chips 110 and 120 that are stacked, not only the PIM region 122 but also the memory cell region 112 may be sufficiently obtained.

An exemplary structure of the memory die 1120 will be described with reference to FIG. 6.

The memory die 1120 includes a first chip 110 and a second chip 120 arranged on the first chip 110. In the first chip 110, a plurality of memory cells are formed in the substrate 115 (see reference numeral 116). The sub-through electrode 118 is arranged in the edge region (see ER2 of FIG. 2) of the first chip 110. In the second chip 120, a PIM circuit 126 and a peri circuit 127 are formed in the substrate 125. The sub-through electrode 128 is arranged in the edge region (see ER2 of FIG. 2) of the second chip 120. The sub-through electrodes 128 and 129 may include tungsten, copper, polymer, carbon nanotube, polysilicon or the like as a filler.

An advantage when the through electrodes 1118 and 1128 are arranged in the edge region ER will be described with reference to FIG. 7.

The memory die 1120 may exchange signals/data with the processor 1040 via the through electrodes 1118 and 1128 and the vertical lines 1116 and 1126, which are arranged in the edge region ER.

On the other hand, when a through electrode 1128a or the like is arranged in a center region CT, the signal/data provided by the processor 1040 is transferred to the memory die 1120 through the micro-bump 1114, a horizontal wiring 1116a, and a through electrode 1118a (see reference numeral A). Therefore, a delay occurs between the through electrode 1118a and the physical layer interface due to the horizontal wiring 1116a.

On the other hand, as in some embodiments of the present disclosure, when the through electrode 1128 or the like is arranged in the edge region ER, the signal/data provided by the processor 1040 is transferred to the memory die 1120 through the micro-bump 1114, the vertical wiring 1116, and the through electrode 1118 (see reference numeral B). Therefore, no delay occurs between the through electrode 1118 and the physical layer interface.

In summary, referring to FIGS. 1 to 7, according to the semiconductor package 100 according to some embodiments of the present disclosure, the memory die 1120 is divided into the first chip 110 and the second chip 120 through a Cell Core Overlap (C2O) technology. The first chip 110 includes a memory cell region 112, and the second chip 120 includes a PIM region 122 and a peri region 124. Therefore, even though the PIM region 122 is added to the memory die 1120, the memory cell region 112 may be sufficiently obtained.

In addition, the through electrode 1118 is arranged in the edge region (ER1 of FIG. 2) of the logic die 1110 facing the processor 1040. Also, the through electrode 1128 is arranged in the edge region (ER2 of FIG. 2) of the memory die 1120, which overlaps the edge region (ER1 of FIG. 2) of the logic die 1110. Therefore, a delay in communication between the memory die 1120 and the processor 1040 may be reduced.

FIGS. 8 to 11 are views illustrating an arrangement of a PIM region and a peri region in a semiconductor package according to some embodiments of the present disclosure. For convenience of description, the description will be based on differences from that described with reference to FIGS. 1 to 7.

The second chip 120 shown in FIGS. 5 and 8 to 11 includes a PIM region 122, a peri region 124, and an edge region (ER2 of FIG. 2). In the second chip 120, the positions of the edge region ER2 are the same as one another, but the arrangement of the PIM region 122 and the peri region 124 may vary depending on design.

In FIG. 5, the peri region 124 may be arranged between the PIM region 122 and the edge region ER2 (or the sub-through region 121).

Referring to FIG. 8, a PIM region 122a and a peri region 124a are arranged to be in direct contact with the edge region ER2 (or the sub-through electrode region 121). The edge region ER2 may have a shape extended in the first direction (e.g., a vertical direction in the drawing), and the PIM region 122a and the peri region 124a may have a shape extended in the second direction (e.g., a horizontal direction in the drawing).

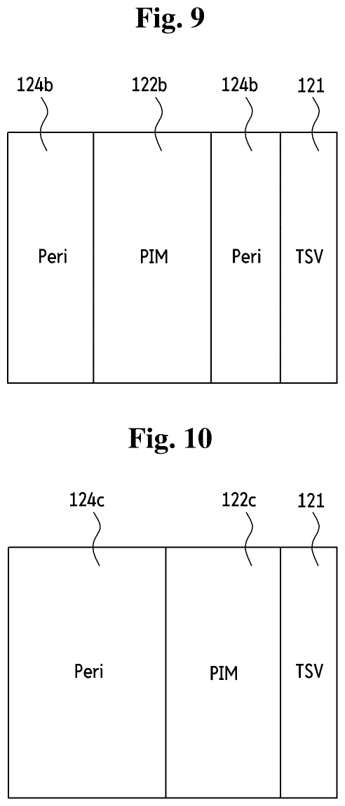

Referring to FIG. 9, there are a plurality of peri regions 124b, and the peri regions 124b may be arranged at both sides of the PIM region 122b.

Referring to FIG. 10, a PIM region 122c may be arranged in contact with the edge region ER2 (or the sub-through electrode region 121). That is, the PIM region 122c may be arranged between a peri region 124c and the edge region ER2 (or the sub-through electrode region 121).

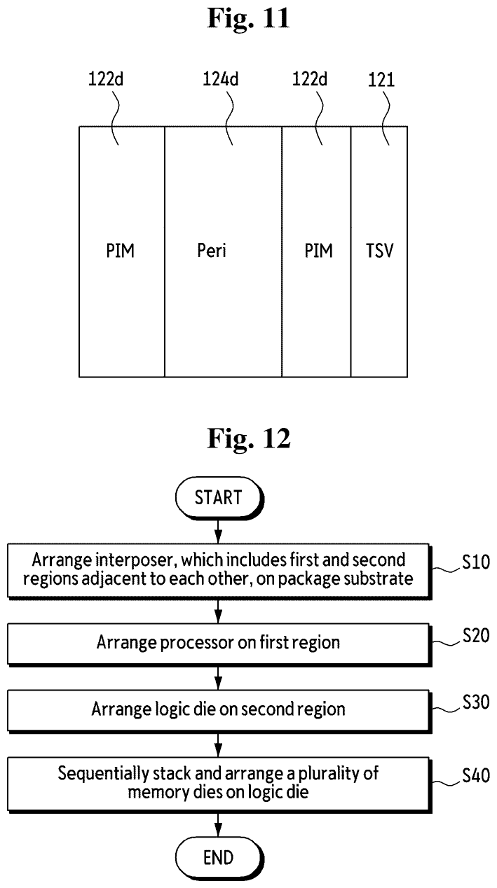

Referring to FIG. 11, there are a plurality of PIM regions 122d, and the PIM regions 122d may be arranged at both sides of a peri region 124d.

FIG. 12 is a flow chart illustrating a method for fabricating a semiconductor package according to some embodiments of the present disclosure.

Referring to FIGS. 1 and 12, an interposer 1200 including a first region and a second region, which are adjacent to one another, is arranged on a package substrate 1220 (S10).

A processor 1040 is arranged on the first region (S20).

A logic die 1110 is arranged on the second region (S30).

A plurality of memory dies 1120 are sequentially stacked and arranged on the logic die 1110 (S40). Any one of the plurality of memory dies 1120 includes a first chip and a second chip, which are stacked, wherein the first chip includes a memory cell region, and the second chip includes a processing in memory (PIM) region and a peri region.

In this case, the order of S20 and S30 may be changed.

In addition, after S30 and S40 are performed, the logic die 1110 in which the plurality of memory dies 1120 are stacked may be arranged on the second region.

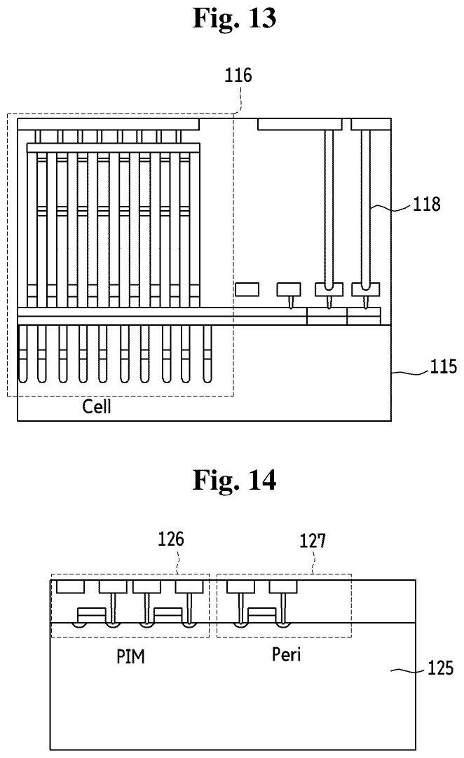

A method for fabricating a memory die used in a semiconductor package according to some embodiments of the present disclosure will be described with reference to FIGS. 13 to 18. FIGS. 13 to 18 are views illustrating intermediate steps to describe a method for fabricating a memory die used in a semiconductor package according to some embodiments of the present disclosure.

Referring to FIG. 13, a memory cell circuit 116 and a sub-through electrode 118 are formed in ae first substrate 115. A memory cell may be implemented in various forms. For example, the memory cell may be implemented as a buried channel array transistor cell (BCAT), a vertical channel transistor (VCT), a vertical stack DRAM (VS-DRAM), etc. In addition, SiGe, an amorphous oxide (e.g., IGZnO(IGZnO)), etc. as well as silicon may be used as a channel material. The sub-through electrode 118 may include tungsten, copper, a polymer, carbon nanotube, polysilicon or the like as a filler.

Referring to FIG. 14, a peri circuit 127 and a PIM circuit 126 are formed in a second substrate 125.

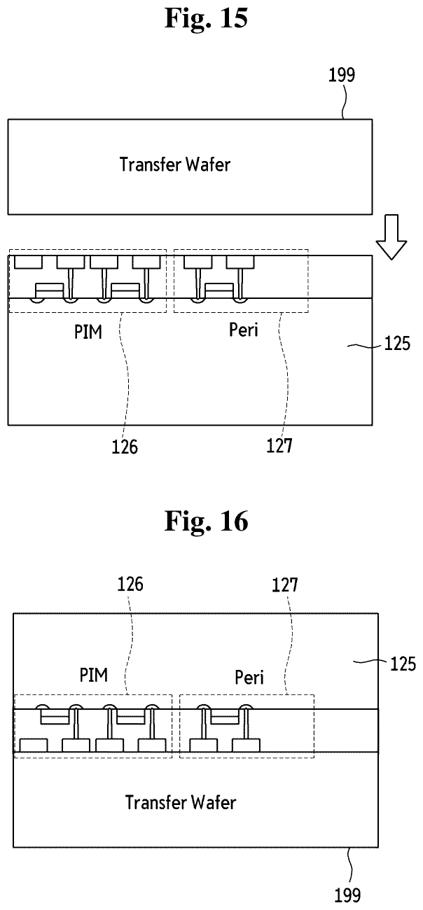

Referring to FIG. 15, a bonding structure is formed by bonding a transfer wafer 199 onto the second substrate 125.

Referring to FIG. 16, the bonding structure is flipped (or inverted) so that a rear surface of the second substrate 125 is directed upward. Subsequently, the rear surface of the second substrate 125 is recessed to reduce a thickness of the second substrate 125.

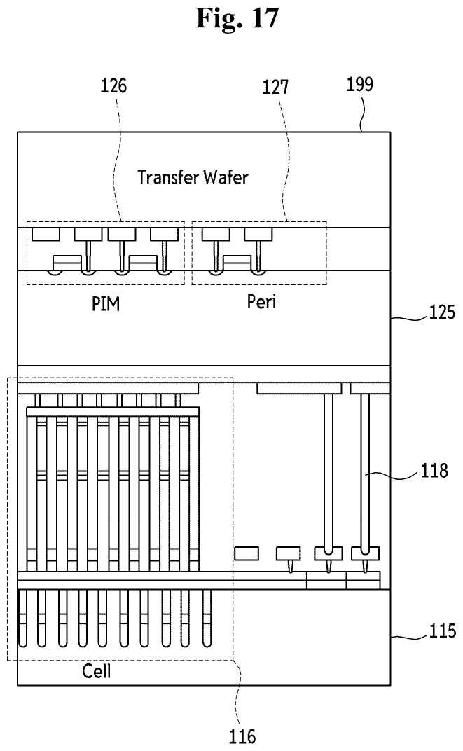

Referring to FIG. 17, after the thickness of the second substrate is reduced, the bonding structure is flipped again so that the transfer wafer 199 is directed upward. Subsequently, the second substrate 125 having a reduced thickness is bonded onto the first substrate 115.

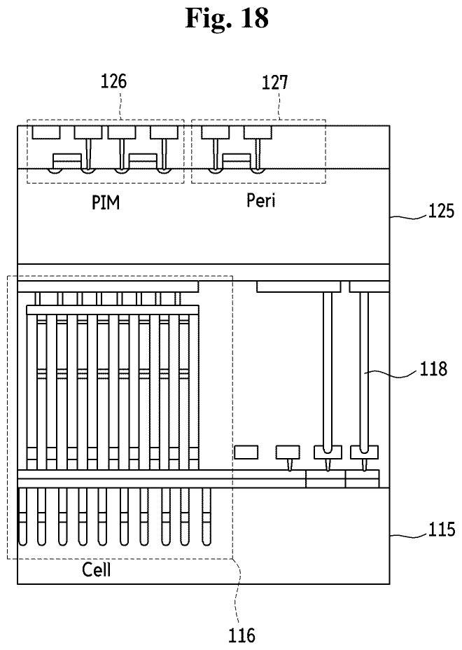

Referring to FIG. 18, the transfer wafer 199 is removed. Subsequently, a sub-through electrode (see 128 of FIG. 6) is formed in the second chip 120. The sub-through electrode 118 of the first chip 110 and the sub-through electrode 128 of the second chip 120 are electrically connected to one another.

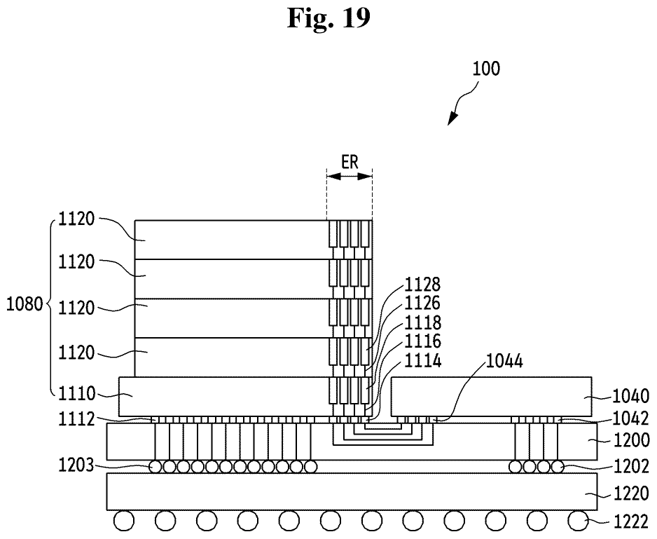

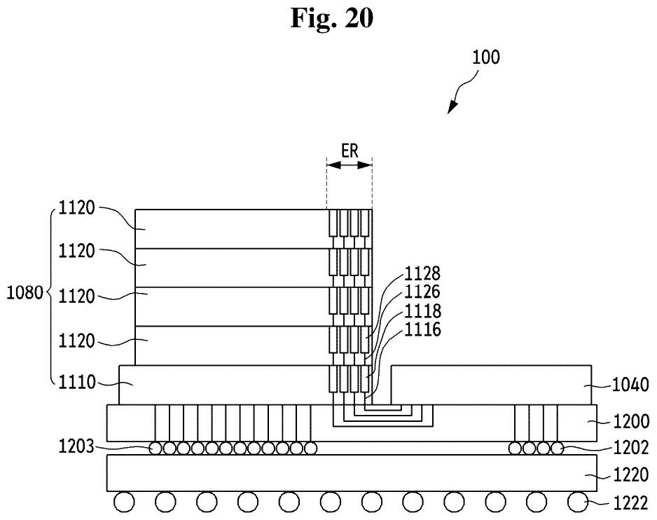

FIG. 19 is a conceptual view illustrating a semiconductor package according to some embodiments of the present disclosure. FIG. 20 is a conceptual view illustrating a semiconductor package according to some embodiments of the present disclosure. For convenience of description, the description will be based on differences from that described with reference to FIGS. 1 to 18.

In the semiconductor package of FIG. 1, the logic die 1100 and the memory die 1120 are connected to one another through the micro-bump 1124, and adjacent memory dies 1120 are connected through the micro-bump. On the other hand, in the semiconductor package of FIG. 19, the logic die 1100 and the memory die 1120 may be connected to one another in a direct bonding manner. In addition, the adjacent memory dies 1120 may be connected to one another in a direct bonding manner. An example of the direct bonding manner may include, but is not limited to, hybrid copper bonding.

Also, in the semiconductor package of FIG. 1, the logic die 1110 and the interposer 1200 are connected to one another through the micro-bumps 1112 and 1114. Also, the processor 1040 and the interposer 1200 are connected to one another through the micro-bumps 1042 and 1044. On the other hand, in the semiconductor package of FIG. 20, the logic die 1110 and the interposer 1200 may be connected to one another in a direct bonding manner, and the processor 1040 and the interposer 1200 may be connected to one another in a direct bonding manner. An example of the direct bonding manner may include, but is not limited to, hybrid copper bonding.

In another embodiment, the interposer 1200 and the package substrate 1220 may be connected to one another without using a plurality of bumps (see 1202 and 1203 of FIG. 1).

Also, in FIGS. 1, 19 and 20, an embodiment in which the processor and the logic die/memory die are electrically connected to one another through the interposer is shown, but the scope of the present disclosure is not limited thereto. That is, in the semiconductor package in which the interposer and the processor are not used, at least one of the stacked memory dies may be divided into the first chip and the second chip, which are stacked. In this case, the first chip may include a memory cell region, and the second chip may include a PIM region.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from the technical spirits and essential characteristics. Thus, the above embodiments are to be considered in all respects as illustrative and not restrictive.

What is claimed is:

1. A semiconductor package comprising:
a package substrate;
a logic die arranged on the package substrate; and
a plurality of memory dies sequentially stacked on the logic die,
wherein at least one of the plurality of memory dies includes a first chip and a second chip, which are stacked,
the first chip includes a memory cell region, and the second chip includes a processing in memory (PIM) region.

2. The semiconductor package of claim 1, wherein the second chip does not include a memory cell region, and further includes a peri region.

3. The semiconductor package of claim 1, wherein the logic die includes a first edge region, the memory die includes a second edge region, a first through electrode is formed in the first edge region, a second through electrode is formed in the second edge region, and the first through electrode and the second through electrode are electrically connected to one another.

4. The semiconductor package of claim 3, wherein the second through electrode includes a first sub-through electrode formed in the first chip and a second sub-through electrode formed in the second chip, and the first sub-through electrode and the second sub-through electrode are electrically connected to another.

5. The semiconductor package of claim 3, wherein a physical layer interface is arranged in the first edge region of the logic die.

6. A semiconductor package comprising:
a package substrate;
an interposer arranged on the package substrate, including a first region and a second region, which are adjacent to another;
a processor arranged on the first region;
a logic die arranged on the second region; and
a plurality of memory dies sequentially stacked on the logic die,
wherein at least one of the plurality of memory dies includes a first chip and a second chip, which are stacked,
the first chip includes a memory cell region, and the second chip includes a processing in memory (PIM) region.

7. The semiconductor package of claim 6, wherein the second chip does not include a memory cell region, and further includes a peri region.

8. The semiconductor package of claim 6, wherein the logic die includes a first edge region facing the processor, the memory die includes a second edge region, a first through electrode is formed in the first edge region, a second through electrode is formed in the second edge region, and the first through electrode and the second through electrode are electrically connected to another.

9. The semiconductor package of claim 8, wherein the second through electrode includes a first sub-through electrode formed in the first chip and a second sub-through electrode formed in the second chip, and the first sub-through electrode and the second sub-through electrode are electrically connected to another.

10. The semiconductor package of claim 8, wherein a physical layer interface is arranged in the first edge region of the logic die.

11. The semiconductor package of claim 8, wherein the second chip further includes a peri region arranged between the second edge region and the PIM region.

12. The semiconductor package of claim 8, wherein the second chip further includes a peri region, and the PIM region and the peri region are arranged to be in direct contact with the second edge region.

13. The semiconductor package of claim 6, wherein the logic die includes a physical layer interface, and
a second through electrode formed in each of the plurality of memory dies is arranged to overlap the physical layer interface.

14. The semiconductor package of claim 8, wherein a micro-bump for electrical connection to the interposer is formed on a bottom surface of the logic die, and
the micro-bump and the second through electrode are connected to another without using a horizontal wiring.

15. The semiconductor package of claim 6, wherein the second chip is arranged on the first chip.

16. A semiconductor package comprising:
a package substrate;
an interposer arranged on the package substrate, including a first region and a second region, which are adjacent to another;
a processor arranged on the first region;
a logic die arranged on the second region; and
a plurality of memory dies sequentially stacked on the logic die,
wherein each of the plurality of memory dies includes a first chip and a second chip, which are sequentially stacked,
the first chip includes a memory cell region, and the second chip includes a processing in memory (PIM) region,
the logic die includes a first edge region facing the processor, each of the plurality of memory dies includes a second edge region that overlaps the first edge region,
a first through electrode is formed in the first edge region, a second through electrode is formed in the second edge region, the second through electrode includes a first sub-through electrode formed in the first chip and a second sub-through electrode formed in the second chip, and
the first through electrode, the first sub-through electrode, and the second sub-through electrode are electrically connected to one another.

17. The semiconductor package of claim 16, wherein the logic die includes a physical layer interface,
the second through electrode formed in each of the plurality of memory dies is arranged to overlap the physical layer interface.

18. The semiconductor package of claim 17, wherein a micro-bump for electrical connection to the interposer is formed on a bottom surface of the logic die, and
the micro-bump and the second through electrode are connected to another without using a horizontal wiring.

19. The semiconductor package of claim 16, wherein the peri region is arranged between the second edge region and the PIM region.
